(19) United States
(12) Patent Application Publication
(10) Pub. No.: US 2022/0123082 A1
(43) Pub. Date: Apr. 21, 2022

(54) DISPLAY PANEL AND DISPLAY DEVICE

(71) Applicant: Xiamen Tianma Micro-Electronics Co., Ltd., Xiamen (CN)

(72) Inventors: Shui HE, Xiamen (CN); Ping AN, Xiamen (CN)

(21) Appl. No.: 17/514,547

(22) Filed: Oct. 29, 2021

(30) Foreign Application Priority Data
May 12, 2021 (CN) 202110518812.5

(51) Int. Cl. H01L 27/32; G09G 3/3233

(52) U.S. Cl. CPC H01L 27/3262; G09G 3/3233; H01L 27/1225; G09G 2300/0842; G09G 2310/061

(57) ABSTRACT

Disclosed are a display panel and a display device. The display panel includes a base substrate, a first transistor, a second transistor, a first conductive layer and a second conductive layer. A second source of the second transistor is connected to a second active layer of the second transistor through the first conductive layer, a second drain is connected to the second active layer through the second conductive layer, and a second gate of the second transistor is overlapped with a channel region, the first conductive layer and the second conductive layer are located in a non-channel region, a width W1 of a first gap between the first conductive layer and the second gate is greater than 0, a width of a second gap W2 between the second conductive layer and the second gate is greater than 0.

### CROSS-REFERENCE TO RELATED APPLICATIONS

This application claims priority to Chinese Patent Application No. 202110518812.5 filed May 12, 2021, the disclosure of which is incorporated herein by reference in its entirety.

### TECHNICAL FIELD

Embodiments of the present disclosure relate to the field of display technologies, and in particular, to a display panel and a display device.

### BACKGROUND

An organic light-emitting diode (OLED) display panel is widely popular with people due to the advantages of self-luminescence, high contrast ratio, thin thickness, high reaction speed, applicability to flexible panels and the like.

An OLED element of the OLED display panel is a current-driven type element, and a respective pixel circuit needs to be disposed to provide a drive current for the OLED element so as to drive the OLED element to emit light. Transistors are disposed in a pixel circuit of the OLED display panel, in the related art, different types of transistors are adopted to satisfy different requirements, and however, there are many problems to be solved upon the different types of transistors being disposed in the pixel circuit.

### SUMMARY

The present disclosure provides a display panel and a display device, so as to solve a problem existing upon different types of transistors being disposed in a pixel circuit in the related art.

In a first aspect, an embodiment of the present disclosure provides a display panel. The display panel includes a base substrate, a first transistor, a second transistor, and a conductive layer. The first transistor and a second transistor are formed on the base substrate, the first transistor includes a first active layer containing a silicon, a first gate, a first source, and a first drain; the second transistor includes a second active layer containing an oxide semiconductor, a second gate, a second source, and a second drain, and the second active layer is located on a side of the first active layer facing away from the base substrate. The conductive layer includes a first conductive layer and a second conductive layer, the first conductive layer and the second conductive layer are located on the second active layer, the second source is electrically connected to the first conductive layer, and the second drain is electrically connected to the second conductive layer. The second active layer includes a channel region and a non-channel region, the second gate and the channel region of the second active layer are overlapped with each other, the first conductive layer and the second conductive layer are disposed in the non-channel region of the second active layer. On a plane parallel to a surface of the base substrate, a first gap is provided between the first conductive layer and the second gate, a second gap is provided between the second conductive layer and the second gate, a width of the first gap is W1, and a width of the second gap is W2, where W1>0, and W2>0.

In a second aspect, an embodiment of the present disclosure further provides a display device, including the display panel described in the first aspect.

### BRIEF DESCRIPTION OF DRAWINGS

FIG. 1 is a schematic diagram of a partial structure of a display panel provided in an embodiment of the present disclosure;

FIG. 2 is a schematic diagram of an enlarged structure of a second transistor provided in an embodiment of the present disclosure;

FIG. 3 is a schematic structural diagram of a pixel circuit provided in an embodiment of the present disclosure;

FIG. 4 is a schematic diagram of an enlarged structure of another second transistor provided in an embodiment of the present disclosure;

FIG. 5 is a schematic diagram of an enlarged structure of still another second transistor provided in an embodiment of the present disclosure;

FIG. 6 a schematic diagram of an enlarged structure of still another second transistor provided in an embodiment of the present disclosure;

FIG. 7 a schematic diagram of an enlarged structure of still another second transistor provided in an embodiment of the present disclosure;

FIG. 8 a schematic diagram of an enlarged structure of still another second transistor provided in an embodiment of the present disclosure;

FIG. 9 is a schematic diagram of a partial structure of another display panel provided in an embodiment of the present disclosure;

FIG. 10 is a schematic diagram of an enlarged structure of a third transistor provided in an embodiment of the present disclosure;

FIG. 11 is a schematic structural diagram of another pixel circuit provided in an embodiment of the present disclosure;

FIG. 12 is a schematic diagram of a partial enlarged structure of a display panel provided in an embodiment of the present disclosure;

FIG. 13 is a schematic diagram of a partial enlarged structure of another display panel provided in an embodiment of the present disclosure;

FIG. 14 is a schematic diagram of a partial enlarged structure of still another display panel provided in an embodiment of the present disclosure;

FIG. 15 is a schematic diagram of a partial structure of still another display panel provided in an embodiment of the present disclosure; and

FIG. 16 is a schematic structural diagram of a display device provided in an embodiment of the present disclosure.

### DETAILED DESCRIPTION

The present disclosure will be further described in detail in conjunction with the drawings and embodiments below. It should be understood that the specific embodiments described herein are merely used for explaining the present disclosure and are not intended to limit the present disclosure. In addition, it should also be noted that, for ease of description, only some, but not all, of the structures related to the present disclosure are shown in the drawings.

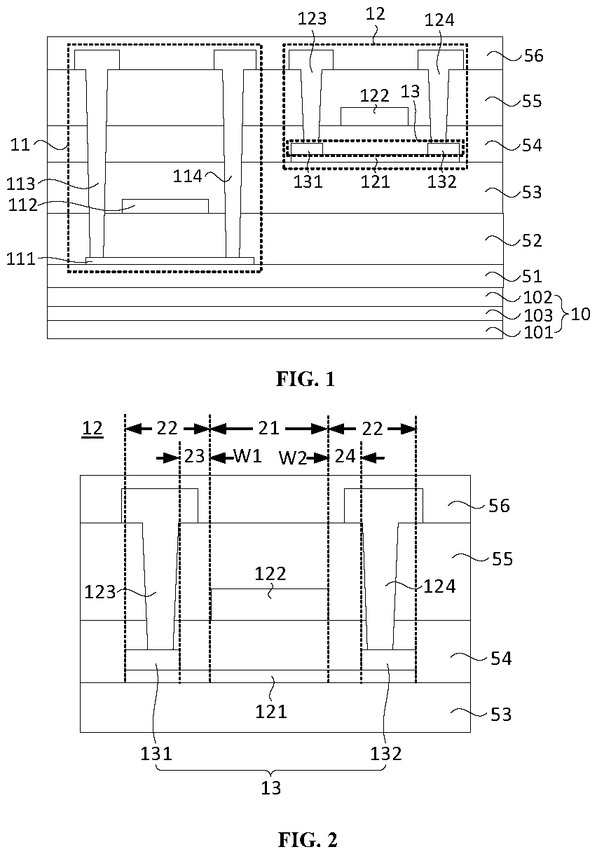

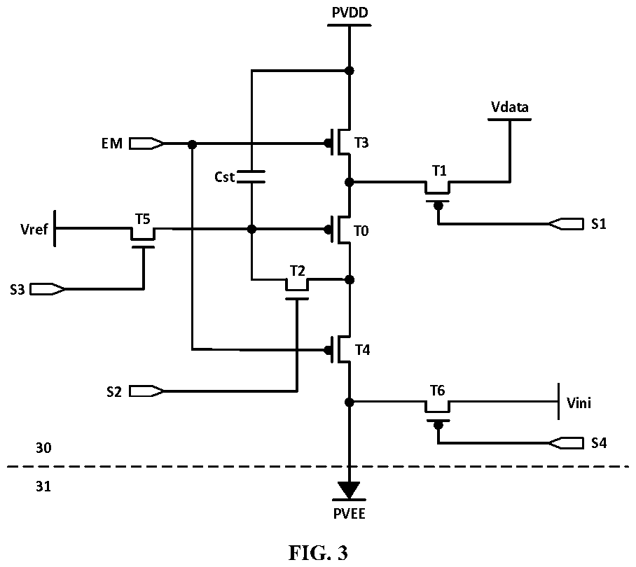

FIG. 1 is a schematic diagram of a partial structure of a display panel provided in an embodiment of the present disclosure, and FIG. 2 is a schematic diagram of an enlarged structure of a second transistor provided in an embodiment of the present disclosure. As shown in FIGS. 1 and 2, the display panel provided in the embodiments of the present disclosure includes a base substrate 10, a first transistor 11, a second transistor 12 and a conductive layer 13. The first transistor 11 and the second transistor 12 are formed on the base substrate 10, the first transistor 11 includes a first active layer 111 containing a silicon, a first gate 112, a first source 113 and a first drain 114. The second transistor 12 includes a second active layer 121 containing an oxide semiconductor, a second gate 122, a second source 123, and a second drain 124. The second active layer 121 is located on a side of the first active layer 111 facing away from the base substrate 10. The conductive layer 13 includes a first conductive layer 131 and a second conductive layer 132, the first conductive layer 131 and the second conductive layer 132 are located on the second active layer 121, the second source 123 is electrically connected to the first conductive layer 131, and the second drain 124 is electrically connected to the second conductive layer 132. The second active layer 121 includes a channel region 21 and a non-channel region 22, the second gate 122 and the channel region 21 are overlapped with each other, the first conductive layer 131 and the second conductive layer 132 are disposed in the non-channel region 22, on a plane parallel to a surface of the base substrate 10, a first gap 23 is provided between the first conductive layer 131 and the second gate 122, and a second gap 24 is provided between the second conductive layer 132 and the second gate 122, a width of the first gap 23 is W1, a width of the second gap 24 is W2, and W1>0, and W2>0.

In an embodiment, as shown in FIGS. 1 and 2, the first transistor 11 and the second transistor 12 are disposed on a side of the base substrate 10, and the first transistor 11 and the second transistor 12 are different types of transistors. In an embodiment, the first active layer 111 of the first transistor 11 includes a silicon, such as a polysilicon or a low temperature polysilicon (LTPS); and the second active layer 121 of the second transistor 12 includes an oxide semiconductor, such as an indium gallium zinc oxide (IGZO). The first transistor 11 and the second transistor 12 may be taken together as a pixel circuit or as part of the pixel circuit, which is not limited in the embodiments of the present disclosure. The second active layer 121 is located on the side of the first active layer 111 facing away from the base substrate 10, so that the second active layer 121 may be prevented from being damaged when the first active layer 111 is subjected to a high-temperature process.

With continued reference to FIGS. 1 and 2, the first source 113 and the first drain 114 of the first transistor 11 are electrically connected to the first active layer 111 through via holes, respectively. The first conductive layer 131 and the second conductive layer 132 are disposed on the second active layer 121 of the second transistor 12, the second source 123 is electrically connected to the first conductive layer 131 through a via hole, and the second drain 124 is electrically connected to the second conductive layer 132 through a via hole. Since the first active layer 111 includes the silicon, so that a surface of the first active layer 111 is easily oxidized, whereby a HF acid treatment needs to be performed on a surface of the first active layer 111 where the via holes are exposed before the first source 113 and the first drain 114 are electrically connected to the first active layer 111 through the via holes. In the related art, via holes connected to the first active layer 111 are usually formed firstly, after the HF acid treatment is performed on the first active layer 111, then via holes connected to the second active layer 121 are formed, so that the second active layer 121 is prevented from being corroded by HF acid. In this embodiment, the first conductive layer 131 and the second conductive layer 132 with good HF acid resistance are disposed on the second active layer 121, so that the first conductive layer 131 and the second conductive layer 132 play a role in protecting the second active layer 121, and whereby the second active layer 121 is prevented from being corroded by HF acid, therefore, the via holes connected to the first active layer 111 and the via holes connected to the second active layer 121 may be prepared in a same technological process, whereby the technological process is reduced, and the preparation cost is reduced while preventing the second active layer 121 from being corroded by the HF acid.

Meanwhile, the first conductive layer 131 and the second conductive layer 132 have a better conductive effect, the electrical connection characteristics between the second active layer 121 and the second source 123 and between the second active layer 121 and the second drain 124 may be improved, and thus the performance of the second transistor 12 may be improved.

With continued reference to FIGS. 1 and 2, the second gate 122 and the channel region 21 of the second active layer 121 are overlapped with each other, the first conductive layer 131 and the second conductive layer 132 are disposed in the non-channel region 22 of the second active layer 121, and on the plane parallel to the surface of the base substrate 10, a first gap 23 with a width greater than 0 exists between the first conductive layer 131 and the second gate 122, and a second gap 24 with a width greater than 0 exists between the second conductive layer 132 and the second gate 122. The second gate 122 and the channel region 21 are overlapped with each other, which means that the second gate 122 and the channel region 21 coincide in a direction perpendicular to a plane where the base substrate 10 is located, that is, an edge of the second gate 122 and an edge of the channel region 21 coincide. In this embodiment, the width W1 of the first gap 23 is set to be greater than 0, and the width of the second gap 24 is set to be greater than 0, so that the second gate 122 is not overlapped with the first conductive layer 131 and the second conductive layer 132 in the direction perpendicular to the plane where the base substrate 10 is located, and therefore, the first conductive layer 131 and the second conductive layer 132 are prevented from shielding the second active layer 121 so as not to facilitate the generation of the channel region, and thus the influence on the characteristics of the second transistor 12 is reduced.

Moreover, the width W1 of the first gap 23 is set to be greater than 0, and the width W2 of the second gap 24 is set to be greater than 0, the diffusion of metal ions in the first conductive layer 131 and the second conductive layer 132 to the second active layer 121 can be reduced, and thus the difficulty of the diffusion of the metal ions in the first conductive layer 131 and the second conductive layer 132 to the channel region 21 is increased, so that a true length of the channel region 21 is ensured, the influence on the performance of the channel region 21 is reduced, and further the performance of the second transistor 12 is favorably improved.

In conclusion, in the display panel provided in the embodiments of the present disclosure, on the plane parallel to the surface of the base substrate 10, the first gap 23 with the width greater than 0 exists between the first conductive layer 131 and the second gate 122, and the second gap 24 with the width greater than 0 exists between the second conductive layer 132 and the second gate 122, so that the second gate 122 is not overlapped with the first conductive layer 131 and the second conductive layer 132 in the direction perpendicular to the plane where the base substrate 10 is located, and therefore, the first conductive layer 131 and the second conductive layer 132 are prevented from shielding the second active layer 121 so as not to facilitate the generation of the channel region, and the influence on the characteristics of the second transistor 12 is reduced. Moreover, the width W1 of the first gap 23 is set to be greater than 0, and the width W2 of the second gap 24 is set to be greater than 0, the diffusion of metal ions in the first conductive layer 131 and the second conductive layer 132 to the second active layer 121 can be reduced, and thus the difficulty of the diffusion of the metal ions in the first conductive layer 131 and the second conductive layer 132 to the channel region 21 is increased, so that the true length of the channel region 21 is ensured, the influence on the performance of the channel region 21 is reduced, and further the performance of the second transistor 12 is favorably improved.

FIG. 3 is a schematic structural diagram of a pixel circuit provided in an embodiment of the present disclosure, as shown in FIGS. 1 to 3, in an embodiment, the display panel provided in the embodiments of the present disclosure further includes a pixel circuit 30, the pixel circuit 30 includes a drive transistor T0, the second drain 124 of the second transistor 12 is connected to a gate of the drive transistor T0, and the second source 123 is connected to a reset signal terminal or a drain of the drive transistor T0, and the second transistor 12 is configured to provide a reset signal for the gate of the drive transistor T0 or to compensate a threshold voltage of the drive transistor T0.

In an embodiment, as shown in FIG. 3, the pixel circuit 30 being a 7T1C pixel circuit (7 transistors and 1 storage capacitor) is used as an example, the pixel circuit 30 may include the drive transistor T0, and, of course, the pixel circuit 30 further includes other transistors T1 to T6, a storage capacitor Cst, and other signal input terminals (such as, S1-S4, Vini, Vref, PVDD, PVEE, EM, and Vdata), which will not be described in detail herein.

A driving process in which the pixel circuit 30 in FIG. 3 drives a light-emitting element 31 is, for example, as follows.

In an initialization stage, a reset transistor T5 is conducted, a reset signal Vref on a reference voltage line is applied to the gate of the drive transistor T0 through the reset transistor T5, at this time, a potential of the gate of the drive transistor T0 is a potential of the reset signal Vref, and therefore the reset of the potential of the gate of the drive transistor T0 is achieved.

In a data signal voltage write stage, a data signal write transistor T1 and the compensation transistor T2 are conducted, and at the same time, the drive transistor T0 is also conducted, and a data signal Vdata on a data line is applied to the gate of the drive transistor T0 through the data signal write transistor T1, the drive transistor T0, and the compensation transistor T2, so that a data voltage is written into the gate of the drive transistor T0.

In a light-emitting stage, a light-emitting control signal EM on a light-emitting control signal line makes a first light-emitting control transistor T3 and a second light-emitting control transistor T4 conduct, and the drive transistor T0 provides a drive current to the light-emitting element 31 according to the data voltage written to the gate of the drive transistor T0, so that the drive transistor T0 drives the light-emitting element 31 to emit light.

In the light-emitting stage, the drive transistor T0 provides a drive current to the light-emitting element 31 according to a gate potential and a source potential of the drive transistor T0 so as to drive the light-emitting element 31 to emit light, and in the light-emitting stage, the source potential of the drive transistor T0 is a fixed potential, so that the gate potential of the drive transistor T0 needs to be very stable so as to ensure that the drive current generated by the drive transistor T0 is accurate enough.

In this embodiment, the second transistor 12 may be set as the reset transistor T5, at this time, the second drain 124 is connected to the gate of the drive transistor T0, the second source 123 is connected to the reset signal terminal for providing the reset signal Vref, and the second transistor 12 is configured to provide the reset signal for the gate of the drive transistor T0. In the second transistor 12, since the second active layer 121 of the second transistor 12 includes the oxide semiconductor, a leakage current is relatively small when the second transistor 12 is in a turning off state compared to the first transistor 11. Therefore, in this embodiment, the second transistor 12 is disposed to be the reset transistor T5, the gate potential of the drive transistor T0 can be ensured to be stable in the light-emitting stage, and whereby the display effect of the display panel is favorably improved.

In an embodiment, the second transistor 12 is disposed to be the compensation transistor T2, at this time, the second drain 124 is connected to the gate of the drive transistor T0, the second source 123 is connected to the drain of the drive transistor T0, and the second transistor 12 is configured to compensate the threshold voltage of the drive transistor T0. Since the leakage current of the second transistor 12 is relatively small when the second transistor 12 is in the turning off state, the second transistor 12 is disposed to be the compensation transistor T2, so as to ensure the gate potential of the drive transistor T0 to be stable during the light-emitting stage, and thus improve the display effect of the display panel.

With continued to reference to FIGS. 1 to 3, in an embodiment, a rate of the second source 123 transmitting a current to the channel region 21 is greater than a rate of the second drain 124 transmitting a current to the channel region 21; or a path length of the second source 123 transmitting a current to the channel region 21 is less than a path length of the second drain 124 transmitting a current to the channel region 21.

In an embodiment, when the second transistor 12 is used as the reset transistor T5 and/or the compensation transistor T2, the second drain 124 is connected to the gate of the drive transistor T0, and the rate of the second drain 124 transmitting the current to the channel region 21 is set to be relatively small, or the path length of the second source 123 transmitting the current to the channel region 21 is set to be relatively long, so that the current transmission capability of the second transistor 12 from the second drain 124 to the second source 123 is relatively weak, therefore in the light-emitting stage, namely when the second transistor 12 is turned off, the leakage current of the second transistor 12 from the second drain 124 to the second source 123 is sufficiently small, so that the gate potential of the drive transistor T0 is ensured to be stable, and further the drive current generated by the drive transistor T0 is ensured to be accurate enough, and thus the display effect of the display panel is favorably improved.

Meanwhile, the rate of the second source 123 transmitting the current to the channel region 21 is set to be relatively large, or the path length of the second source 123 transmitting the current to the channel region 21 is set to be relatively short, so that the current transmission capability of the second transistor 12 from the second source 123 to the second drain 124 is relatively strong, and the second transistor 12 has good response speed and current transmission characteristics. Thus, when the second transistor 12 is used as the reset transistor T5, in the initialization stage, the reset signal Vref on the reference voltage line may be applied to the gate of the drive transistor T0 more quickly from the second source 123 of the second transistor 12, so that the rapid reset of the gate potential of the drive transistor T0 is achieved. When the second transistor 12 is used as the compensation transistor T2, in the data signal voltage write stage, the data signal Vdata on the data line may be applied to the gate of the drive transistor T0 more quickly through the second source 123 of the second transistor 12, so that the data voltage may be written into the gate of the drive transistor T0 quickly.

FIG. 4 is a schematic diagram of an enlarged structure of another second transistor provided in an embodiment of the present disclosure, as shown in FIG. 4, in an embodiment, W2>W1.

As shown in FIG. 4, the width W1 of the first gap 23 determines a migration path of carriers from the second source 123 toward the channel region 21, and the width W2 of the second gap 24 determines a migration path of carriers from the second drain 124 toward the channel region 21, in this embodiment, the width W1 of the first gap 23 is relatively small by setting W2>W1, therefore, when the second source 123 of the second transistor 12 transmits a signal to the second drain 124, a path of an initial position (the first gap 23) where the carriers need to migrate is relatively short, so that the migration time is shortened, and a response rate of the second transistor 12 is increased. Meanwhile, the width W2 of the second gap 24 is set to be relatively large, when the second drain 124 of the second transistor 12 leaks electricity to the second source 123, a path of an initial position (the second gap 24) where the carriers need to migrate is relatively long, so that the migration time is longer, and the response of the second transistor 12 is relatively difficult, whereby the transmission of the leakage current is more favorably inhibited. When the second drain 124 of the second transistor 12 is connected to the gate of the drive transistor T0, the stability of the gate potential of the drive transistor T0 is favorably improved.

With continued reference to FIG. 4, in an embodiment, there is a following formula, e.g., (W2−W1)≤1 μm.

When the second transistor 12 is turned on, the carriers are transmitted from the second source 123 to the second drain 124 along a path of the second source 123->the first gap 23->the channel region 21->the second gap 24->the second drain 124, and if the width W2 of the second gap 24 is too large, then the path of this process is too long, so that the response rate of the second transistor 12 is affected. In this embodiment, the width W2 of the second gap 24 is not too large by setting (W2−W1)≤1 μm, so that a transmission path of the carriers from the second source 123 to the second drain 124 is not too long, and further the response rate of the second transistor 12 upon being turned on is ensured.

In an embodiment, the width W1 of the first gap 23 and the width W2 of the second gap 24 satisfy following equations: 0.5 μm≤W1≤3 μm, and 0.5 μm≤W2≤3 μm.

The width W1 of the first gap 23 and the width W2 of the second gap 24 are reasonably set, so that the width W1 of the first gap 23 and the width W2 of the second gap 24 are not too small, the diffusion of metal ions in the first conductive layer 131 and the second conductive layer 132 to the second active layer 121 can be reduced, and thus the difficulty of the diffusion of the metal ions in the first conductive layer 131 and the second conductive layer 132 to the channel region 21 is increased, the real length of the channel region 21 is ensured, and the performance of the second transistor 12 is favorably improved. Meanwhile, it is ensured that the width W1 of the first gap 23 and the width W2 of the second gap 24 are not too large, and therefore the response rate of the second transistor 12 upon being turned on is ensured.

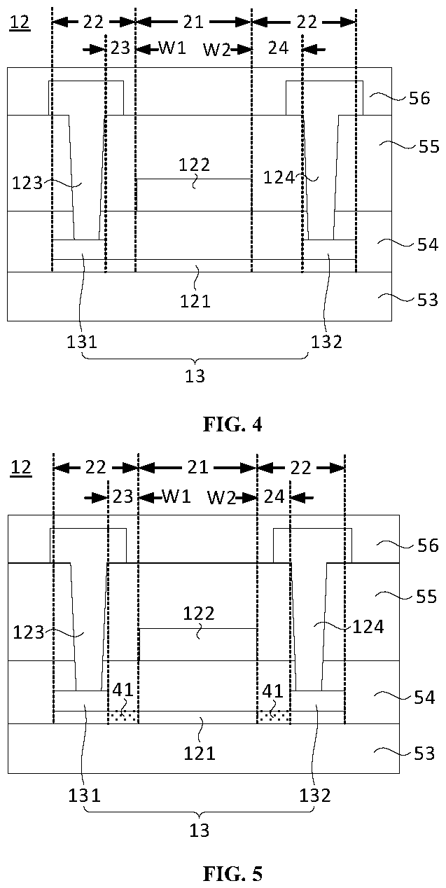

FIG. 5 is a schematic diagram of an enlarged structure of still another second transistor provided in an embodiment of the present disclosure, as shown in FIG. 5, in an embodiment, a region of the second active layer 121 overlapped with the first gap 23 and/or the second gap 24 is at least partially doped with a first dopant 41, and a region of the second active layer 121 overlapped with the first conductive layer 131 and/or the second conductive layer 132 is at least partially undoped with the first dopant 41.

As shown in FIG. 5, the first gap 23 and/or the second gap 24 are appropriately doped with the first dopant 41, an energy level difference between the channel region 21 and the first conductive layer 131 and/or the second conductive layer 132 can be reduced, thereby facilitating the migration of the carriers from the second source 123 to the second drain 124. At the same time, the region of the second active layer 121 overlapped with the first conductive layer 131 and/or the second conductive layer 132 is at least partially undoped with the first dopant 41, so that the technological process is reduced, and thus the preparation cost is reduced, at this time, the first conductive layer 131 and the second conductive layer 132 play a role in conducting the second active layer 121 with the second source 123 and the second drain 124, respectively.

It should be noted that the region of the second active layer 121 overlapped with the first gap 23 and/or the second gap 24 refers to a region where the second active layer 121 is overlapped with the first gap 23 and/or the second gap 24 in the direction perpendicular to the plane where the base substrate 10 is located. A region where the first conductive layer 131 and/or the second conductive layer 132 are overlapped with the second active layer 121 is a region of the second active layer 121 overlapped with the first conductive layer 131 and/or the second conductive layer 132 in the direction perpendicular to the plane where the base substrate 10 is located.

It should be noted that in the present application, the overlapping between different structures refers to a region where in the direction perpendicular to the plane where the base substrate 10 is located, perpendicular projections of the different structures on the plane where the base substrate 10 is located overlap, which will not described in detail in subsequent embodiments.

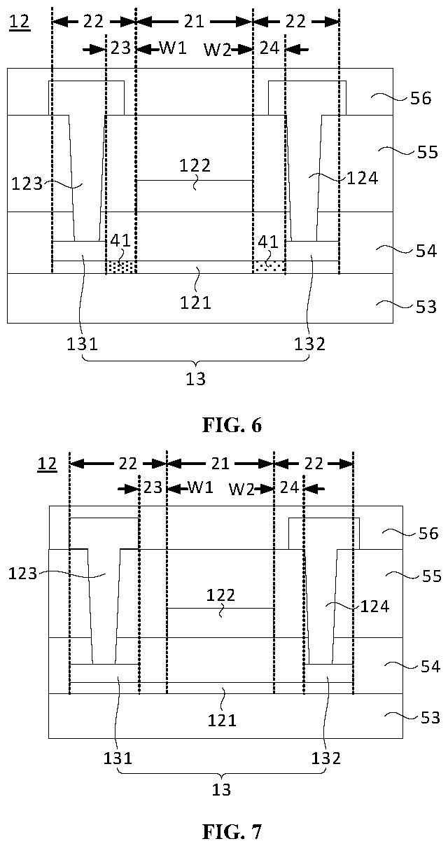

FIG. 6 a schematic diagram of an enlarged structure of still another second transistor provided in an embodiment of the present disclosure, as shown in FIG. 6, in an embodiment, the first dopant 41 doped in the region of the second active layer 121 overlapped with the first gap 23 has a concentration C1, the first dopant 41 doped in the region of the second active layer 121 overlapped with the second gap 24 has a concentration C2, where C1>C2≥0.

As shown in FIG. 6, the concentration C1 of the first dopant 41 doped in the region of the second active layer 121 overlapped with the first gap 23 is set to be greater than the concentration C2 of the first dopant 41 doped in the region of the second active layer 121 overlapped with the second gap 24, so that the concentration C1 of the first dopant 41 of the second active layer 121 at the first gap 23 is relatively large, therefore an energy level difference between the first conductive layer 131 and the channel region 21 is further reduced, the migration of the carriers from the second source 123 to the channel region 21 is facilitated, the current transmission from the second source 123 to the second drain 124 is relatively easier, and the response rate of the second transistor 12 upon being turned on is increased. Meanwhile, the concentration C2 of the first dopant 41 of the second active layer 121 at the second gap 24 is set to be relatively small, and even the second active layer 121 is set to be undoped with the first dopant 41, so that an energy level difference between the second conductive layer 132 and the channel region 21 is relatively large, the leakage current transmission from the second drain 124 to the second source 123 is relatively more difficult, and the leakage current of the second transistor 12 upon being in the turning off state is reduced.

It should be noted that in this embodiment, the concentration of the first dopant 41 refers to a volume concentration or an atomic concentration, and in this application, the concentration of the dopant refers to a volume concentration or a molecular concentration or an atomic concentration, which will not described in detail in subsequent embodiments.

FIG. 7 a schematic diagram of an enlarged structure of still another second transistor provided in an embodiment of the present disclosure, as shown in FIG. 7, in an embodiment, an overlapping area of the first conductive layer 131 and the second active layer 121 is S1, an overlapping area of the second conductive layer 132 and the second active layer 121 is S2, where S1>S2.

As shown in FIG. 7, the overlapping area S1 between the first conductive layer 131 and the second active layer 121 is set to be greater than the overlapping area S2 between the second conductive layer 132 and the second active layer 121, so that a larger overlapping area exists between the first conductive layer 131 and the second active layer 121, and a large amount of charge may pass between the first conductive layer 131 and the second active layer 121 within the same time, whereby a faster charge transfer from the second source 123 to the second drain 124 is caused, and thus the response rate of the second transistor 12 upon being turned on is increased. Meanwhile, a smaller overlapping area exists between the first conductive layer 131 and the second active layer 121, a smaller amount of charge may pass between the first conductive layer 131 and the second active layer 121 within the same time, whereby a slower charge transfer from the second drain 124 to the second source 123 is caused, and thus the leakage current may be effectively suppressed.

With continued reference to FIGS. 1 to 7, in an embodiment, a resistivity of the first conductive layer 131 is less than a resistivity of the second conductive layer 132.

The resistivity of the first conductive layer 131 is set to be less than the resistivity of the second conductive layer 132, so that the resistivity of the first conductive layer 131 is relatively small, the charge transfer speed from the second source 123 to the second drain 124 may be favorably increased, and thus the response rate of the second transistor 12 upon being turned on may be increased. At the same time, the resistivity of the second conductive layer 132 is set to be relatively large, so that a corresponding speed at which charges are transferred from the second drain 124 to the second source 123 is favorably weakened, and thus the leakage current may be effectively suppressed.

FIG. 8 a schematic diagram of an enlarged structure of still another second transistor provided in an embodiment of the present disclosure, as shown in FIG. 8, in an embodiment, each of the first conductive layer 131 and the second conductive layer 132 includes a base material 130 and a second dopant 42, a resistivity of the second dopant 42 is less than a resistivity of the base material 130, and a concentration C3 of the second dopant 42 in the first conductive layer 131 is greater than a concentration C4 of the second dopant 42 in the second conductive layer 132.

As shown in FIG. 8, the concentration C3 of the second dopant 42 in the first conductive layer 131 is set to be greater than the concentration C4 of the second dopant 42 in the second conductive layer 132, so that the concentration C3 of the second dopant 42 in the first conductive layer 131 is relatively great, and thus the resistivity is relatively small, the charge transfer speed from the second source 123 to the second drain 124 may be favorably increased, and thus the response rate of the second transistor 12 upon being turned on may be increased, at the same time, so that the concentration C4 of the second dopant 42 in the second conductive layer 132 is relatively small, and thus the resistivity is relatively large, so that a corresponding speed at which charges are transferred from the second drain 124 to the second source 123 is favorably weakened, and thus the leakage current may be effectively suppressed.

Further, the first conductive layer 131 and/or the second conductive layer 132 may be an alloy, or may be any combination of other conductive materials, which may be set by those skilled in the art according to practical needs, and is not limited in the embodiments of the present disclosure.

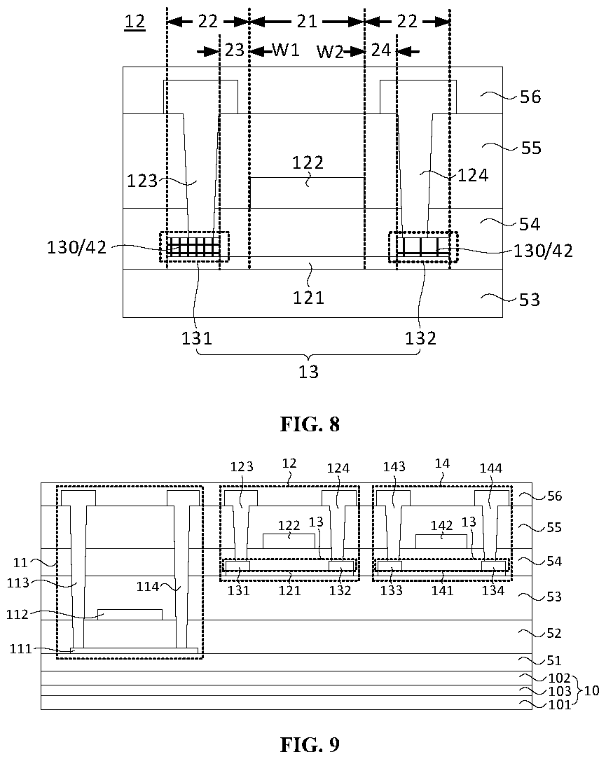

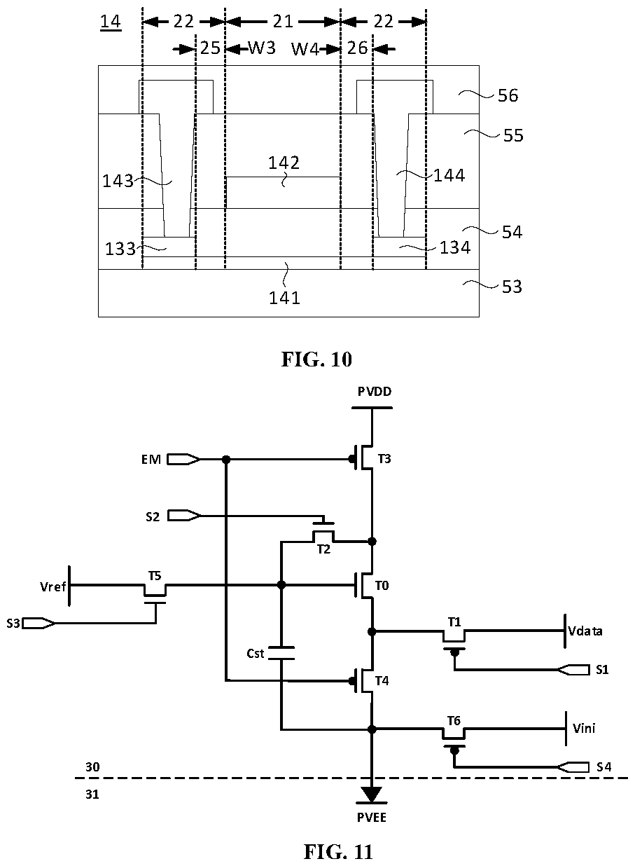

FIG. 9 is a schematic diagram of a partial structure of another display panel provided in an embodiment of the present disclosure, FIG. 10 is a schematic diagram of an enlarged structure of a third transistor provided in an embodiment of the present disclosure, as shown in FIG. 9 and FIG. 10, in an embodiment, the display panel provided in the embodiments of the present disclosure further includes a third transistor 14. The third transistor 14 includes a third active layer 141 including an oxide semiconductor, a third gate 142, a third source 143, and a third drain 144. The third transistor 14 includes a third conductive layer 133 and a fourth conductive layer 134, the third active layer 141 includes a channel region 21 and a non-channel region 22, the third gate 142 is overlapped with the channel region 21, the third conductive layer 133 and the fourth conductive layer 134 are disposed in the non-channel region 22. On a plane parallel to a surface of the base substrate 10, and a third gap 25 is located between the third conductive layer 133 and the third gate 142, a fourth gap 26 is located between the fourth conductive layer 134 and the third gate 142, a width of the third gap 25 is W3, and a width of the fourth gap 26 is W4, where W3>0 and W4>0.

In an embodiment, as shown in FIGS. 9 and 10, the third transistor 14 is also disposed on a side of the base substrate 10, and the third active layer 141 of the third transistor 14 includes an oxide semiconductor, such as an indium gallium zinc oxide (IGZO). The third active layer 141 may be located on a side of the first active layer 111 facing away from the base substrate 10, so that the third active layer 141 may be protected from being damaged when the first active layer 111 is subjected to a high-temperature process.

With continued reference to FIGS. 9 and 10, in an embodiment, the third active layer 141 of the third transistor 14 is provided with the third conductive layer 133 and the fourth conductive layer 134, and the third source 143 is electrically connected to the third conductive layer 133 through via holes, and the third drain 144 is electrically connected to the third conductive layer 133 through via holes. Since the first active layer 111 includes the silicon, so that a surface of the first active layer 111 is easily oxidized, whereby a HF acid treatment needs to be performed on a surface of the first active layer 111 where the via holes are exposed before the first source 113 and the first drain 114 are electrically connected to the first active layer 111 through the via holes. In this embodiment, the third conductive layer 133 and the fourth conductive layer 134 with better HF acid resistance are disposed on the third active layer 141, so that the third conductive layer 133 and the fourth conductive layer 134 play a role in protecting the third active layer 141, and whereby the third active layer 141 is prevented from being corroded by HF acid, therefore the via holes connected to the active layer 111 and the via holes connected to the third active layer 141 may be prepared in a same technological process, whereby the technological process is reduced, and the preparation cost is reduced while preventing the third active layer 141 from being corroded by the HF acid.

Meanwhile, the third conductive layer 133 and the fourth conductive layer 134 have a better conductive effect, the electrical connection characteristics between the third active layer 141 and the third source 143 and the third drain 144 may be improved, and thus the performance of the third transistor 13 may be improved.

With continued reference to FIGS. 9 and 10, in an embodiment, the third gate 142 and the channel region 21 of the third active layer 141 are overlapped with each other, and the third conductive layer 133 and the fourth conductive layer 134 are disposed in the non-channel region 22 of the third active layer 141, and on the plane parallel to the surface of the base substrate 10, a third gap 25 with a width greater than 0 exists between the third conductive layer 133 and the third gate 142, and a fourth gap 26 with a width greater than 0 exists between the fourth conductive layer 134 and the third gate 142. The fourth gap 26 and the channel region 21 are overlapped with each other, which means that the third gate 142 and the channel region 21 coincide in a direction perpendicular to a plane where the base substrate 10 is located, that is, an edge of the third gate 142 and an edge of the channel region 21 coincide. In this embodiment, the width W3 of the third gap 25 is set to be greater than 0, and the width of the fourth gap 26 is set to be greater than 0, so that the third gate 142 is not overlapped with the third conductive layer 133 and the fourth conductive layer 134 in the direction perpendicular to the plane where the base substrate 10 is located, and therefore, the third conductive layer 133 and the fourth conductive layer 134 are prevented from shielding the third active layer 141 so as not to facilitate the generation of the channel region, and thus the influence on the characteristics of the third transistor 14 is reduced.

Moreover, the width W3 of the third gap 25 is set to be greater than 0, and the width W4 of the fourth gap 26 is set to be greater than 0, the diffusion of metal ions in the third conductive layer 133 and the fourth conductive layer 134 to the third active layer 141 can be reduced, and the difficulty of the diffusion of the metal ions in the third conductive layer 133 and the fourth conductive layer 134 to the channel region 21 is increased, so that a true length of the channel region 21 is ensured, the influence on the performance of the channel region 21 is reduced, and further the performance of the third transistor 14 is favorably improved.

It should be noted that the transistor and the drive transistor in the above pixel circuit 30 may be a N-type transistor or a P-type transistor, and moreover, a silicon-based transistor, such as a a-Si transistor, a P—Si transistor, a LTPS transistor, or an oxide transistor, such as an indium gallium zinc oxide (IGZO) transistor, may also be adopted, which is not limited in the embodiments of the present disclosure.

In an embodiment, as shown in FIG. 3, the drive transistor T0 is a PMOS LTPS transistor, the reset transistor T5 is an NMOS IGZO transistor, and the compensation transistor T2 is an NMOS IGZO transistor. Or, as shown in FIG. 11, the drive transistor T0 is an NMOS IGZO transistor, the reset transistor T5 is an NMOS IGZO transistor, and the compensation transistor T2 is an NMOS IGZO transistor.

Moreover, in an embodiment, the data signal write transistor T1, the first light-emitting control transistor T3, the second light-emitting control transistor T4, and the transistor T6 may each be the LTPS transistor, and in an embodiment, the above-described transistor may be the P-type transistor, which is not limited in the embodiments of the present disclosure.

FIG. 11 is a schematic structural diagram of another pixel circuit provided in an embodiment of the present disclosure, as shown in FIGS. 9 to 11, and optionally, the display panel provided in the embodiments of the present disclosure includes a pixel circuit 30, the third transistor 14 is the drive transistor T0 of the pixel circuit 30, and the second transistor 12 is the reset transistor T5 or the compensation transistor T2 of the pixel circuit 30.

In an embodiment, as shown in FIG. 11, the pixel circuit 30 being a 7T1C pixel circuit (7 transistors and 1 storage capacitor) is used as an example, the pixel circuit 30 may include the drive transistor T0, and, of course, the pixel circuit 30 further includes other transistors T1 to T6, a storage capacitor Cst, and other signal input terminals (such as, S1-S4, Vini, Vref, PVDD, PVEE, EM and Vdata), which will not be described in detail herein.

A driving process in which the pixel circuit 30 drives the light-emitting element 31 shown in FIG. 11 is, for example, the driving process in which the pixel circuit 30 drives the light-emitting element 31 shown in FIG. 3, which will not be described in detail herein.

In the light-emitting stage, the drive transistor T0 provides a drive current to the light-emitting element 31 according to a gate potential and a source potential of the drive transistor T0 so as to drive the light-emitting element 31 to emit light, and in the light-emitting stage, the source potential of the drive transistor T0 is a fixed potential, so that the gate potential of the drive transistor T0 needs to be very stable so as to ensure that the drive current generated by the drive transistor T0 is accurate enough.

In this embodiment, the second transistor 12 may be set as the reset transistor T5, at this time, the second drain 124 is connected to the gate of the drive transistor T0, the second source 123 is connected to the reset signal terminal for providing the reset signal Vref, and the second transistor 12 is configured to provide the reset signal for the gate of the drive transistor T0. In the second transistor 12, since the second active layer 121 of the second transistor 12 includes the oxide semiconductor, a leakage current is relatively small when the second transistor 12 is in a turning off state compared to the first transistor 11. Therefore, in this embodiment, the second transistor 12 is disposed to be the reset transistor T5, the gate potential of the drive transistor T0 can be ensured to be stable in the light-emitting stage, and whereby the display effect of the display panel is favorably improved.

In an embodiment, the second transistor 12 is disposed to be the compensation transistor T2, at this time, the second drain 124 is connected to the gate of the drive transistor T0, the second source 123 is connected to the drain of the drive transistor T0, and the second transistor 12 is configured to compensate the threshold voltage of the drive transistor T0. Since the leakage current of the second transistor 12 is relatively small when the second transistor 12 is in the turning off state, the second transistor 12 is disposed to be the compensation transistor T2, so as to ensure that the gate potential of the drive transistor T0 to be stable during the light-emitting stage, and thus improve the display effect of the display panel.

Meanwhile, since the third active layer 141 of the third transistor 14 includes the oxide semiconductor, with respect to a silicon-based semiconductor transistor, the third transistor 14 is disposed to be the drive transistor T0 of the pixel circuit 30, so that of the drive transistor T0 has a better uniformity threshold voltage, a less leakage current, and a lower hysteresis effect.

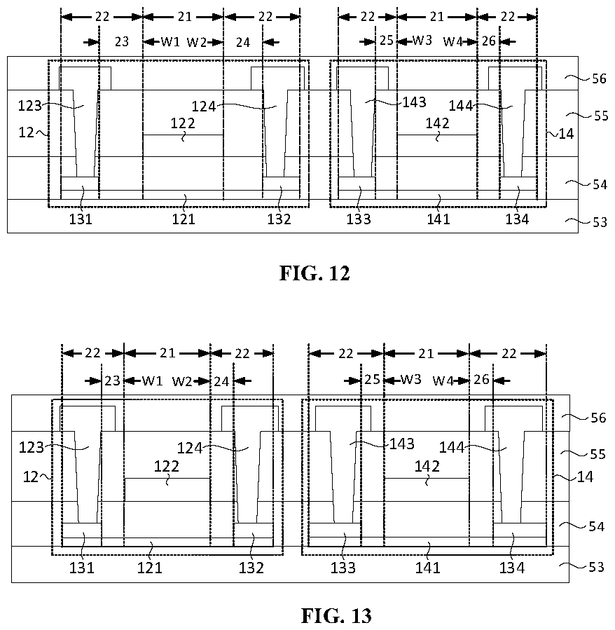

FIG. 12 is a schematic diagram of a partial enlarged structure of a display panel provided in an embodiment of the present disclosure, as shown in FIG. 12, in an embodiment, W11 is a larger one of the W1 and the W2, W22 is a larger one of the W3 and the W4, and W11>W22.

W11 is the larger one of the W1 and the W2, W22 is the larger one of the W3 and the W4, in an embodiment, if W1>W2, then W11=W1, and if W1<W2, then W11=W2, if W1=W2, then W11=W1=W2, similarly, if W3>W4, then W22=W3, if W3<W4, then W22=W4, and if W3=W4, then W22=W3=W4.

As shown in FIG. 12, in this embodiment, the W11 is set to be greater than W22, so that the width W1 of the first gap 23 of the second transistor 12 and/or the width W2 of the second gap 24 of the second transistor 12 is relatively large, a leakage current is relatively small when the second transistor 12 is in a turning off state, and thus, when the second transistor 12 is used as the reset transistor T5 and/or the compensation transistor T2, the gate potential of the drive transistor T0 is ensured to be stable in the light-emitting stage, and further the drive current generated by the drive transistor T0 is ensured to be accurate enough, and thus the display effect of the display panel is favorably improved. Meanwhile, the width W3 of the third gap 25 and/or the width W4 of the fourth gap 26 of the third transistor 14 are set to be smaller, so that the length of the channel region 21 of the third active layer 141 in the third transistor 14 is increased, and the driving capability of the drive transistor T0 is improved.

With continued reference to FIG. 12, in an embodiment, W3=W4, and W3<W1, or W3<W2.

As shown in FIG. 12, the width W3 of the third gap 25 of the third transistor 14 and the width W4 of the fourth gap 26 of the third transistor 14 are set to be less than the width W1 of the first gap 23 and the width W2 of the second gap 24, so that the width W1 of the first gap 23 of the second transistor 12 and the width W2 of the second gap 24 of the second transistor 12 are both larger, the leakage current when the second transistor 12 is in the turning off state can be further reduced, and therefore, when the second transistor 12 is used as the reset transistor T5 and/or the compensation transistor T2, the gate potential of the drive transistor T0 is ensured to be stable in the light-emitting stage, and further the drive current generated by the drive transistor T0 is ensured to be accurate enough, and thus the display effect of the display panel is further improved. Meanwhile, the width W3 of the third gap 25 of the third transistor 14 and the width W4 of the fourth gap 26 of the third transistor 14 are set to be smaller, the length of the channel region 21 of the third active layer 141 in the third transistor 14 can be further increased, and therefore the driving capability and the response speed of the drive transistor T0 are improved.

FIG. 13 is a schematic diagram of a partial enlarged structure of another display panel provided in an embodiment of the present disclosure, as shown in FIG. 13, in an embodiment, an overlapping area of the first conductive layer 131 and the second active layer 121 is S1, and an overlapping area of the second conductive layer 132 and the second active layer 121 is S2; an overlapping area of the third conductive layer 133 and the third active layer 141 is S3, and an overlapping area of the fourth conductive layer 134 and the third active layer 141 is S4; and where S11 is a larger one of the S1 and the S2, and S22 is a larger one of the S3 and the S4, where S11<S22.

S11 is the larger one of the S1 and the S2, and S22 is the larger one of the S3 and the S4, in an embodiment, if S1>S2, then S11=S1, if S1<S2, then S11=S2, and if S1=S2, then S11=S1=S2; similarly, if S3>S4, then S22=S3, if S3<S4, then S22=S4, and if S3=S4, then S22=S3=S4.

As shown in FIG. 13, in this embodiment, the S11 is set to be less than the S22, so that a larger overlapping area exists between the third conductive layer 133 and/or the fourth conductive layer 134 and the third active layer 141, and a large amount of charge may pass between the third conductive layer 133 and/or the fourth active layer 134 and the third active layer 141 within the same time, whereby a faster charge transfer between the third source 143 and the third drain 144 is caused, and thus the response capability of the third transistor 14 (drive transistor T0) is improved.

Meanwhile, a smaller overlapping area exists between the first conductive layer 131 and/or the second conductive layer 132 and the second active layer 121, a relatively small amount of charges may pass between the first conductive layer 131 and/or the second conductive layer 132 and the second active layer 121 within the same time, whereby a relatively slow charge transfer between the second drain 124 and the second source 123 is caused, and thus the leakage current of the second transistor 12 (the reset transistor T5 and/or the compensation transistor T2) may be effectively suppressed.

With continued reference to FIG. 13, in an embodiment, S3=S4 and S3>S1, or S3>S2.

As shown in FIG. 13, the overlapping area S3 between the third conductive layer 133 and the third active layer 141 and the overlapping area S4 between the fourth conductive layer 134 and the third active layer 141 are both set to be greater than the overlapping area S1 between the first conductive layer 131 and the second active layer 121 and the overlapping area S2 between the second conductive layer 132 and the second active layer 121, so that the overlapping area S3 of the third transistor 14 and the overlapping area S4 of the third transistor 14 are both large, and a large amount of charge may pass between the third conductive layer 133 and/or the fourth active layer 134 and the third active layer 141 within the same time, whereby a charge transfer rate between the third source 143 and the third drain 144 is further increased, and thus the response capability of the third transistor 14 (drive transistor T0) is further improved.

Meanwhile, the overlapping area S1 of the second transistor 12 and the overlapping area S2 of the second transistor 12 are set to be small, a relatively small amount of charges may pass between the first conductive layer 131 as well as the second conductive layer 132 and the second active layer 121 within the same time, whereby a charge transfer rate between the second drain 124 and the second source 123 is further reduced, and thus the leakage current of the second transistor 12 (the reset transistor T5 and/or the compensation transistor T2) may be effectively suppressed.

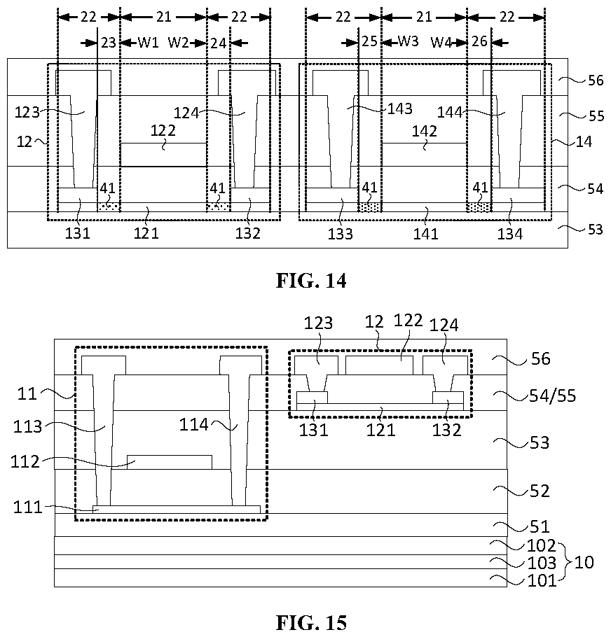

FIG. 14 is a schematic diagram of a partial enlarged structure of still another display panel provided in an embodiment of the present disclosure, as shown in FIG. 14, in an embodiment, a first dopant 41 doped in a region of the second active layer 121 overlapped with the first gap 23 has a concentration C1, a first dopant 41 doped in a region of the second active layer 121 overlapped with the second gap 24 has a concentration C2; a first dopant 41 doped in a region of the third active layer 141 overlapped with the third gap 25 has a concentration C3, a first dopant 41 doped in a region of the third active layer 141 overlapped with the fourth gap 26 has a concentration C4; and C11 is a larger one of the C1 and the C2, and C22 is a larger one of the C3 and the C4, where 0≤C11<C22.

C11 is the larger one of the C1 and the C2, and C22 is the larger one of the C3 and the C4, in an embodiment, if C1>C2, then C11=C1, if C1<C2, then C11=C2, and if C1=C2, then C11=C1=C2; similarly, if C3>C4, then C22=C3, if C3<C4, then C22=C4, and if C3=C4, then C22=C3=C4.

As shown in FIG. 14, in this embodiment, the C11 is set to be less than the C22, so that the concentration C3 of the first dopant 41 doped in the region of the third active layer 141 overlapped with the third gap 25 and/or the concentration C4 of the first dopant 41 doped in the region of the third active layer 141 overlapped with the fourth gap 26 are relatively large, whereby an energy level difference between the third conductive layer 133 and/or the fourth conductive layer 134 and the channel region 21 of the third active layer 141 is reduced, the current transmission between the third source 143 and the third drain 144 is relatively easier, and thus the response capability and the current transmission capability of the third transistor 14 (drive transistor T0) are improved.

Meanwhile, the concentration C1 of the first dopant 41 doped in the region of the second active layer 121 overlapped with the first gap 23 and/or the concentration C2 of the first dopant 41 doped in the region of the second active layer 121 overlapped with the second gap 24 are set to be relatively small, and even the second active layer 121 is set to be undoped with the first dopant 41, so that an energy level difference between the first conductive layer 131 and/or the second conductive layer 132 and the channel region 21 of the second active layer 121 is relatively large, the leakage current transmission between the second drain 124 and the second source 123 is relatively more difficult, and the leakage current of the second transistor 12 (the reset transistor T5 and/or the compensation transistor T2) upon being in the turning off state is reduced.

With continued reference to FIG. 14, in an embodiment, C3=C4 and C3>C1, or C3>C2.

As shown in FIG. 13, the concentration C3 of the first dopant 41 doped in the region of the third active layer 141 overlapped with the third gap 25 and the concentration C4 of the first dopant 41 doped in the region of the third active layer 141 overlapped with the fourth gap 26 are both set to be greater than the concentration C1 of the first dopant 41 doped in the region of the second active layer 121 overlapped with the first gap 23 and the concentration C2 of the first dopant 41 doped in the region of the second active layer 121 overlapped with the second gap 24, so that the concentration C3 of the first dopant 41 doped in the region of the third active layer 141 overlapped with the third gap 25 and the concentration C4 of the first dopant 41 doped in the region of the third active layer 141 overlapped with the fourth gap 26 are set to be relatively large; whereby an energy level difference between the third conductive layer 133 and the fourth conductive layer 134 and the channel region 21 of the third active layer 141 is reduced, the current transmission between the third source 143 and the third drain 144 is relatively easier, and thus the response capability and the current transmission capability of the third transistor 14 (drive transistor T0) are further improved.

Meanwhile, the concentration C1 of the first dopant 41 doped in the region of the second active layer 121 overlapped with the first gap 23 and the concentration C2 of the first dopant 41 doped in the region of the second active layer 121 overlapped with the second gap 24 are set to be relatively small, and even the second active layer 121 is set to be undoped with the first dopant 41, so that an energy level difference between the first conductive layer 131 and the second conductive layer 132 and the channel region 21 of the second active layer 121 is relatively large, the leakage current transmission difficulty between the second drain 124 and the second source 123 is further improved, and thus the leakage current of the second transistor 12 (the reset transistor T5 and/or the compensation transistor T2) upon being in the turning off state is further reduced.

FIG. 15 is a schematic diagram of a partial structure of still another display panel provided in an embodiment of the present disclosure, as shown in FIG. 15, the first source 113, the first drain 114, the second source 123, the second drain 124 and the second gate 122 are located on a same layer, and the second gate 122 is located on a side of the second active layer 121 facing away from the base substrate 10.

As shown in FIG. 15, the first source 113, the first drain 114, the second source 123, the second drain 124 and the second gate 122 are manufactured on a same layer, on one hand, these film layers may be manufactured through a same process, one process can be reduced, and therefore the purposes of reducing the production cost and reducing the thickness of the base substrate are achieved. On the other hand, a depth of a via hole for connecting the first source 113 and the first drain 114 with the first active layer 111 can be shortened, the manufacturing difficulty of the via hole is reduced, and the electric connection between the first source 113 as well as the first drain 114 with the first active layer 111 is facilitated.

With continued reference to FIGS. 1 to 15, in an embodiment, the base substrate 10 includes a first substrate 101 and a second substrate 102, and an insulating layer 103 located between the first substrate 101 and the second substrate 102. When the display panel is prepared, the first substrate 101 is prepared on a rigid substrate, and the pixel circuits and the light-emitting elements are prepared on the second substrate 102. The structure of the base substrate 10 described above is adopted, even though the first substrate 101 may be damaged when the rigid substrate is removed by laser lift-off, the integrity of the second substrate 102 can still be ensured, thereby ensuring the integrity of the entire display panel.

In other embodiments, the base substrate 10 may further include only a single-layer substrate. Moreover, the base substrate 10 may also disposed to be a flexible base substrate or a rigid base substrate, which is not limited in the embodiments of the present disclosure.

It should be noted that other function film layers may be set by those skilled in the art according to practical needs. In an embodiment, with continued reference to FIGS. 1 to 15, a buffer layer 51 is disposed on a side of the base substrate 10 facing the first active layer 111. The buffer layer 51 ay play a role of shockproof, buffer and isolation. Alternatively, with continued reference to FIGS. 1 to 15, for example, a side of the base substrate 10 further includes a first gate insulating layer 52, a first interlayer insulating layer 53, a second gate insulating layer 54, and a second interlayer insulating layer 55 and a planarization layer 56 which are disposed in a stacked manner, which is not limited in the embodiments of the present disclosure.

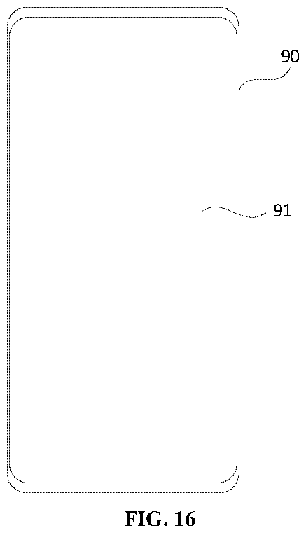

Based on the same inventive concept, an embodiment of the present disclosure further provides a display device, and FIG. 16 is a schematic structural diagram of a display device provided in an embodiment of the present disclosure, as shown in FIG. 16, the display device 90 includes the display panel 91 described in any of the embodiments of the present disclosure, and thus the display device 90 provided in the embodiments of the present disclosure has the technical effects of the technical schemes in any of the above embodiments, and the same or corresponding structures and explanations of terms as those in the above embodiments are not described in detail herein. The display device 90 provided in the embodiments of the present disclosure may be a mobile phone as shown in FIG. 16, and may also be any electronic product with a display function, including but not limited to following categories: a television, a notebook computer, a desktop display, a tablet computer, a digital camera, an intelligent bracelet, an intelligent glass, a vehicle-mounted display, medical equipment, industrial control equipment, a touch interaction terminal and the like, which is not particularly limited in the embodiments of the present disclosure.

It should be noted that the above-mentioned contents are only the preferred embodiments of the present disclosure and the technical principles applied thereto. It is to be understood by those skilled in the art that the present disclosure is not limited to the particular embodiments described herein, and that various variations, rearrangements and substitutions may be made without departing from the scope of protection of the present disclosure. Therefore, although the present disclosure has been described in detail with reference to the above embodiments, the present disclosure is not limited to the above embodiments, and may further include other equivalent embodiments without departing from the concept of the present disclosure, and the scope of the present disclosure is defined by the appended claims.

What is claimed is:

1. A display panel, comprising:
a base substrate;
a first transistor and a second transistor, wherein the first transistor and the second transistor are formed on the base substrate, wherein the first transistor comprises a first active layer containing a silicon, a first gate, a first source, and a first drain; the second transistor comprises a second active layer containing an oxide semiconductor, a second gate, a second source, and a second drain, and the second active layer is located on a side of the first active layer facing away from the base substrate; and
a conductive layer, wherein the conductive layer comprises a first conductive layer and a second conductive layer, wherein the first conductive layer and the second conductive layer are located on the second active layer, the second source is electrically connected to the first conductive layer, and the second drain is electrically connected to the second conductive layer;
wherein the second active layer comprises a channel region and a non-channel region, the second gate and the channel region of the second active layer are overlapped with each other, the first conductive layer and the second conductive layer are disposed in the non-channel region of the second active layer, and
wherein on a plane parallel to a surface of the base substrate, a first gap is provided between the first conductive layer and the second gate, a second gap is provided between the second conductive layer and the second gate, a width of the first gap is W1, and a width of the second gap is W2, W1>0, and W2>0.

2. The display panel of claim 1, wherein the display panel comprises a pixel circuit, the pixel circuit comprises a drive transistor, the second drain of the second transistor is connected to a gate of the drive transistor, the second source is connected to a reset signal terminal or a drain of the drive transistor, and the second transistor is configured to provide a reset signal for the gate of the drive transistor or to compensate a threshold voltage of the drive transistor.

3. The display panel of claim 2, wherein a rate of the second source transmitting a current to the channel region is greater than a rate of the second drain transmitting a current to the channel region; or,
a path length of the second source transmitting a current to the channel region is less than a path length of the second drain transmitting a current to the channel region.

4. The display panel of claim 2, wherein W2>W1.

5. The display panel of claim 4, wherein (W2−W1)≤1 μm.

6. The display panel of claim 2, wherein a region of the second active layer overlapped with at least one of the first gap or the second gap is at least partially doped with a first dopant, and a region of the second active layer overlapped with at least one of the first conductive layer or the second conductive layer is at least partially undoped with the first dopant.

7. The display panel of claim 6, wherein the first dopant doped in the region of the second active layer overlapped with the first gap has a concentration of C1, the first dopant doped in the region of the second active layer overlapped with the second gap has a concentration of C2, wherein C1>C2≥0.

8. The display panel of claim 2, wherein an overlapping area of the first conductive layer and the second active layer is S1, an overlapping area of the second conductive layer and the second active layer is S2, wherein S1>S2.

9. The display panel of claim 2, wherein a resistivity of the first conductive layer is less than a resistivity of the second conductive layer.

10. The display panel of claim 9, wherein each of the first conductive layer and the second conductive layer comprises a base material and a second dopant, a resistivity of the second dopant is less than a resistivity of the base material, and a concentration C3 of the second dopant in the first conductive layer is larger than a concentration C4 of the second dopant in the second conductive layer.

11. The display panel of claim 1, wherein the display panel further comprises a third transistor, and the third transistor comprises a third active layer containing an oxide semiconductor, a third gate, a third source and a third drain;
the third transistor comprises a third conductive layer and a fourth conductive layer, the third active layer comprises a channel region and a non-channel region, the third gate and the channel region of the third active layer are overlapped with each other, and the third conductive layer and the fourth conductive layer are disposed in the non-channel region of the third active layer, and
on the plane parallel to the surface of the base substrate, a third gap is provided between the third conductive layer and the third gate, a fourth gap is provided between the fourth conductive layer and the third gate, a width of the third gap is W3, and a width of the fourth gap is W4, wherein W3>0, and W4>0.

12. The display panel of claim 11, wherein the display panel comprises a pixel circuit, the third transistor is a drive transistor of the pixel circuit, and the second transistor is a reset transistor of the pixel circuit or a compensation transistor of the pixel circuit.

13. The display panel of claim 12, wherein W11 is a larger one of the W1 and the W2, W22 is a larger one of the W3 and the W4, and W11>W22.

14. The display panel of claim 12, wherein W3=W4 and W3<W1, or wherein W3=W4 and W3<W2.

15. The display panel of claim 12, wherein an overlapping area of the first conductive layer and the second active layer is S1, and an overlapping area of the second conductive layer and the second active layer is S2;
an overlapping area of the third conductive layer and the third active layer is S3, and an overlapping area of the fourth conductive layer and the third active layer is S4; and
S11 is a larger one of the S1 and the S2, and S22 is a larger one of the S3 and the S4, wherein S11<S22.

16. The display panel of claim 12, wherein S3=S4 and S3>S1, or wherein S3>S2.

17. The display panel of claim 11, wherein a first dopant doped in a region of the second active layer overlapped with the first gap has a concentration C1, a first dopant doped in a region of the second active layer overlapped with the second gap has a concentration C2;
a first dopant doped in a region of the third active layer overlapped with the third gap has a concentration C3, a first dopant doped in a region of the third active layer overlapped with the fourth gap has a concentration C4; and
C11 is a larger one of the C1 and the C2, and C22 is a larger one of the C3 and the C4, wherein 0≤C11<C22.

18. The display panel of claim 17, wherein C3=C4 and C3>C1, or wherein C3>C2.

19. The display panel of claim 1, wherein the first source and the first drain are located on a same layer, and the second source, the second drain and the second gate are located on a same layer, and wherein the second gate is located on a side of the second active layer facing away from the base substrate.

20. A display device, comprising a display panel;
wherein the display panel comprises:
a base substrate;
a first transistor and a second transistor, wherein the first transistor and the second transistor are formed on the base substrate, wherein the first transistor comprises a first active layer containing a silicon, a first gate, a first source, and a first drain; the second transistor comprises a second active layer containing an oxide semiconductor, a second gate, a second source, and a second drain, and the second active layer is located on a side of the first active layer facing away from the base substrate; and
a conductive layer, wherein the conductive layer comprises a first conductive layer and a second conductive layer, wherein the first conductive layer and the second conductive layer are located on the second active layer, the second source is electrically connected to the first conductive layer, and the second drain is electrically connected to the second conductive layer;
wherein the second active layer comprises a channel region and a non-channel region, the second gate and the channel region of the second active layer are overlapped with each other, the first conductive layer and the second conductive layer are disposed in the non-channel region of the second active layer, and
wherein on a plane parallel to a surface of the base substrate, a first gap is provided between the first conductive layer and the second gate, a second gap is provided between the second conductive layer and the second gate, a width of the first gap is W1, and a width of the second gap is W2, W1>0, and W2>0.
